(19) United States
(12) Patent Application Publication
(10) Pub. No.: US 2024/0332127 A1
(43) Pub. Date: Oct. 3, 2024

(54) ON-PACKAGE EMBEDDED COOLING DEVICE

(71) Applicant: Intel Corporation, Santa Clara, CA (US)

(72) Inventors: Eng Kwong Lee, Bayan Lepas (MY); Tin Poay Chuah, Bayan Baru (MY); Chew Ching Lim, Bayan Lepas (MY)

(73) Assignee: Intel Corporation, Santa Clara, CA (US)

(21) Appl. No.: 18/191,242

(22) Filed: Mar. 28, 2023

(51) Int. Cl. H01L 23/38

(52) U.S. Cl. CPC H01L 23/38; H10N 10/17; H10N 10/8556

(57) ABSTRACT

In one embodiment, an integrated circuit package includes an integrated heat spreader (IHS) that incorporates a Peltier element. The IHS may include one or more Peltier elements, which may be in a top portion of the IHS. The Peltier element(s) may be electrically connected to the package substrate through a trace on a sidewall of the IHS.

### BACKGROUND

Thermal challenges in multi-chip packages are becoming more pronounced in recent years, especially on high power, high performance package designs. The various chips on the multi-chip package can have different power densities (measured in Watts per unit Area), which can result in various hot spots on the package that can lead to thermal limitations of the overall package. Traditional thermal solutions have included passive heatsinks or active fan heatsinks, but these solutions might not provide enough cooling for certain multi-chip packages.

### BRIEF DESCRIPTION OF THE DRAWINGS

FIG. 1 illustrates an example multi-chip package incorporating a Peltier-type cooling device in accordance with embodiments herein.

FIG. 2 illustrates an example Peltier element that may be implemented in embodiments herein.

FIGS. 3A-3B illustrate cross-sectional views of example multi-chip packages with Peltier-type cooling devices in accordance with embodiments herein.

FIG. 4 illustrates an example system that includes an integrated circuit package with a heat spreader incorporating a Peltier element in accordance with embodiments herein.

FIGS. 5A-5B illustrate detailed views of an example heat spreader with an integrated Peltier element in accordance with embodiments herein.

FIGS. 6A-6B illustrate example dimensional changes for embodiments of the present disclosure with respect to current heat spreader solutions.

FIGS. 7-8 illustrates detailed views of other example heat spreaders with an integrated Peltier element in accordance with embodiments herein.

FIG. 9 is a top view of a wafer and dies that may be included in a microelectronic assembly, in accordance with any of the embodiments disclosed herein.

FIG. 10 is a cross-sectional side view of an integrated circuit device assembly that may include embodiments disclosed herein.

FIG. 11 is a cross-sectional side view of an integrated circuit device that may be included in a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

Multi-die packages are known to have different power densities on their various dies. In general, the thermal design requirements for these packages are based on power consumption of the dies without considering the area in which the power is being distributed. However, power density has become a thermal design limiter in recent package designs. Power density is typically defined as the power consumption across a given area of a die. The higher the power density, the more challenging a thermal design becomes. This also implies high power over a large die may not be as challenging as lower power over a small die due to concentrated hot spot.

Existing package cooling solutions include liquid cooling, vapor chamber cooling, or a large heat sink mass coupled with an active fan. These solutions are more costly compared to traditional passive heat sink solutions and require parametric analyses to ensure hot spot temperatures are meeting the junction temperature requirements for the chips on the package. In some cases, where the hot spot temperature exceeds junction temperature (due to high power density), the dimension of the cooling solution needs to be increased, which results in a larger form factor for the overall package.

Embodiments herein may include an on-package Peltier-based cooling device that is embedded in an Integrated Heat Spreader (IHS) on the package top side. The cooling device can include one or more Peltier elements that provide a cooling effect to the chip(s) of the package, increasing the package heat dissipation capability before an external heat sink or other type of cooling solution is attached to the package. The Peltier elements can be laid out uniformly across the entirety or majority of the IHS, or in particular locations of the IHS, e.g., according to known hot spot locations on the package.

There are several advantages that can be seen with such cooling devices, both in the platform design and the user experience. For example, due to the increased package cooling capability provided, the package can used at higher operating temperatures. In addition, embodiments herein can allow for higher Thermal Design Power (TDP) or Processor Base Power for an integrated circuit package, which in turn, allows for higher performance package designs to be implemented. Similarly, the increased package cooling capability allows more margin for higher operating power modes (e.g., Turbo Boost (PL2 limit)) and longer durations in such modes of operation. Further, the increased package cooling capability can allow for lower skin temperatures in mobile/tablet computing device implementations, smaller external heatsinks, and/or operation without a fan (quieter operation), all of which can lead to better user experiences.

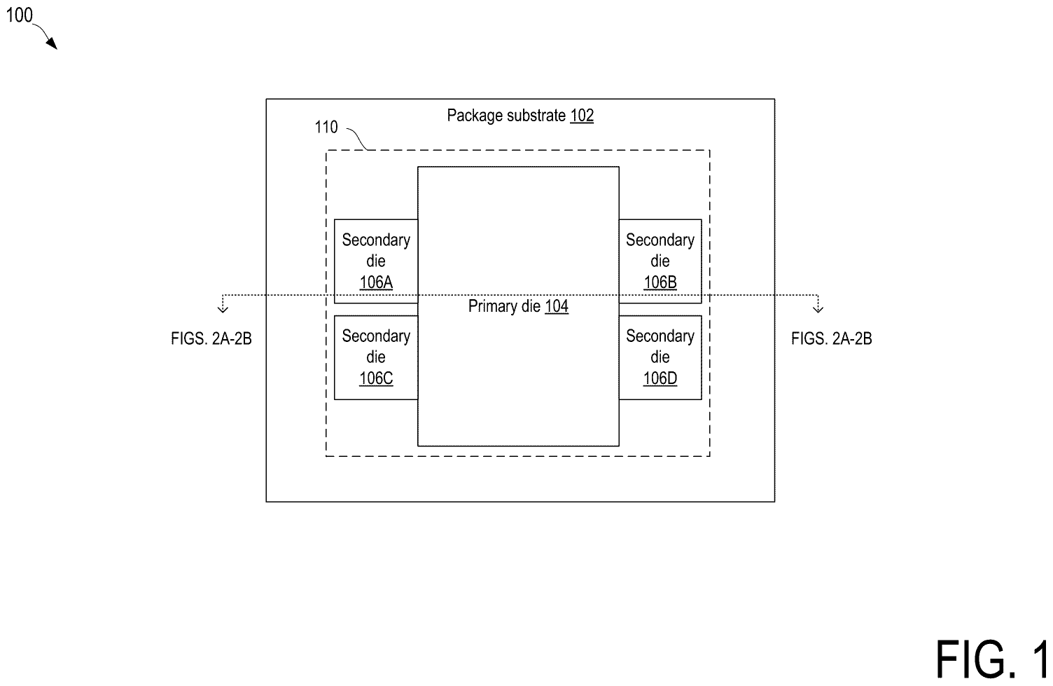

FIG. 1 illustrates an example multi-chip package 100 incorporating a Peltier-type cooling device 110 in accordance with embodiments herein. The package 100 includes a package substrate 102 with a primary or first die 104 and multiple other or secondary dies 106 thereon. In various implementations, the primary die 104 may be a logic or processor die. For example, die 104 may include logic and other circuitry to implement a field programmable gate array (FPGA) fabric. In various implementations, secondary dies 106 may be implemented as one of, for example, a high bandwidth memory (HBM) die, transceiver die (e.g., high speed serial interfaces (HSSI)), or another type of logic circuit die or combination of dies, and may include logic and other circuitry to implement such functions. The package substrate 102 may include circuitry to connect the dies 104, 106 to a main circuit board (e.g., motherboard or main board) and/or to interconnect the dies 104, 106 with one another. In some embodiments, for instance, the package substrate 102 may include an interconnect bridge circuitry die that interconnects two or more of the dies 104, 106.

In one example, the total TDP of the package 102 may be 160 W, with 100 W on the primary die 104 and 15 W on each of the secondary dies 106. A traditional design would consider 100 W on the primary die 104 as being the thermal limiter for the package, but in some instance, the secondary dies 106 may be the actual thermal limiters. For instance, the junction temperature on the secondary dies 106 may be approximately 98° C. while the junction temperature of the primary die 104 may be approximately 86° C. In this situation, the thermal limiter is the lower power secondary dies 106 rather than the primary die 104, and the cooling requirements of the overall package design may become more stringent. Accordingly, the cooling device 110 may implement one or more cooling elements (e.g., a Thermoelectric Cooler (TEC)) that utilize the Peltier effect (Peltier elements) to address this.

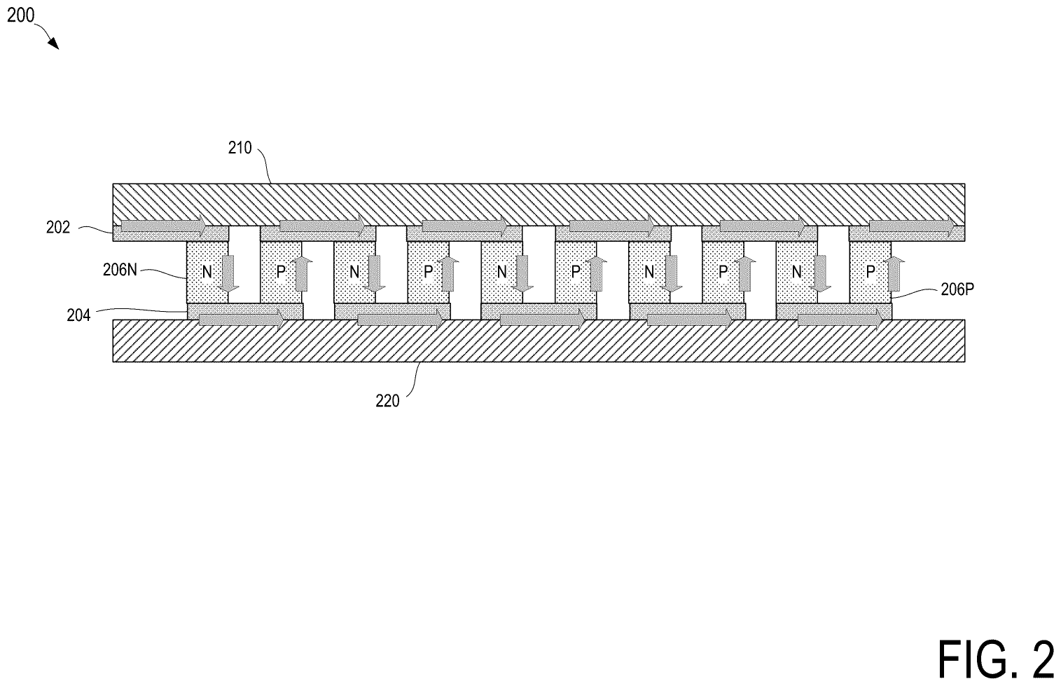

FIG. 2 illustrates an example Peltier element 200 that may be implemented in embodiments herein. A Peltier element, such as 200, is a type of thermoelectric heat pump that transfers heat from one side of the element to another based on the Peltier effect. The principle of Peltier effect is to create a heat flux at the junction of two different types of materials, which will either emit or absorb heat when electrical current flows through the junction. The example Peltier element 200 includes a set of n-type semiconductors 206N and p-type semiconductors 206P placed in between the thermally conductive plates 210, 220 (electrically connected with conductive portions 202, 204, which may be, e.g., metal). In various implementations, the p-type semiconductor materials 206P include silicon doped or implanted with elements such as boron (B), aluminum (Al), gallium (Ga), germanium (Ge), etc. In various implementations, the n-type semiconductor materials 206N include silicon doped or implanted with elements such as phosphorus (P), arsenic (As), or antimony (Sb), etc.

Current flows in series through the of n-type and p-type semiconductors 206 as shown by the arrows in FIG. 2, alternating between the n-type and p-type semiconductors 206. The plates 210, 220 may be made of any suitable thermally conductive material, such as ceramic. When DC current flows across the junction of the semiconductor elements 206, a temperature difference is created, and a cold side (e.g., 220) absorbs heat, which is then transferred to the “hot” side (e.g., 210). Thus, the Peltier element 200 may be placed on an object so that its cold side (e.g., 220) is coupled to a heat source (e.g., a die) to absorb the heat, which is then dissipated to the hot side (e.g., 210).

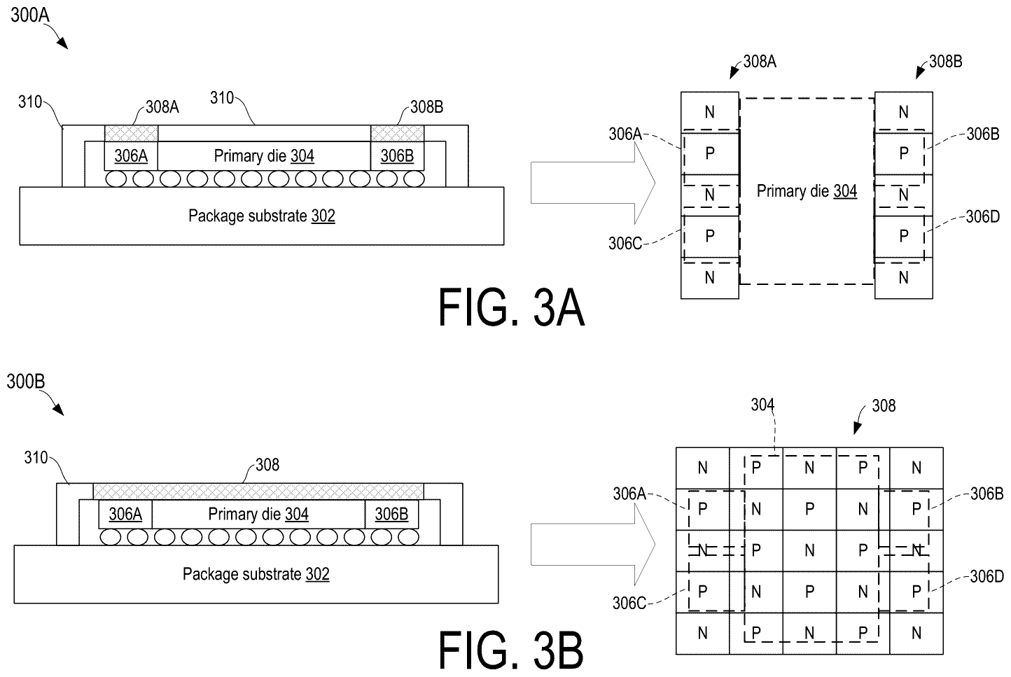

FIGS. 3A-3B illustrate cross-sectional views of example multi-chip packages 300A, 300B with Peltier-type cooling devices in accordance with embodiments herein. The example packages 300A, 300B may be implemented in the same or similar manner as the package 100 of FIG. 1, but with different implementations of Peltier elements 308. For instance, the package substrates 302 may be implemented in the same or similar manner as the package substrate 102, the primary die 304 may be implemented in the same or similar manner as the primary die 104, and the secondary dies 306 may be implemented in the same or similar manner as the secondary dies 106. The dies 304, 306 are encased on the packages 300 by an IHS 310, which includes at least one Peltier element 308. Referring to the example shown in FIG. 3A, the example package 300A includes Peltier elements 308A, 308B in the IHS 310 that are positioned only over the secondary dies 306 of the package 300A. In contrast, the example package 300B of FIG. 3B has an IHS 310 with a larger Peltier element 308 positioned over all of the dies 304, 306 of the package. The right side of each illustration shows an example arrangement of the p-type and n-type semiconductor elements (e.g., similar to 206 of FIG. 2) in each Peltier element 308.

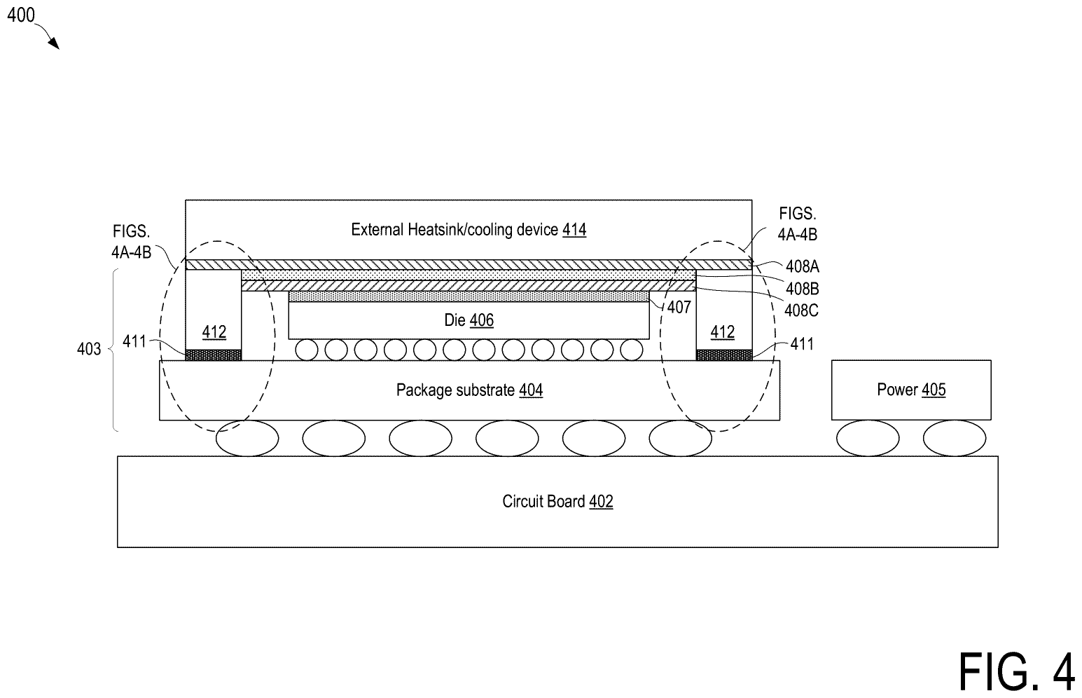

FIG. 4 illustrates an example system 400 that includes integrated circuit package with a heat spreader incorporating a Peltier element in accordance with embodiments herein. The system 400 includes a circuit board 402, which may be implemented as a motherboard or main board of a computing system (e.g., similar to 1002). The system 400 also includes an integrated circuit package 403 coupled to the circuit board 402, which includes a package substrate 404 and an integrated circuit die 406 coupled to the package substrate 404. The die 406 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 406 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 406 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 404 may provide electrical connections between the die 406 and the circuit board 402.

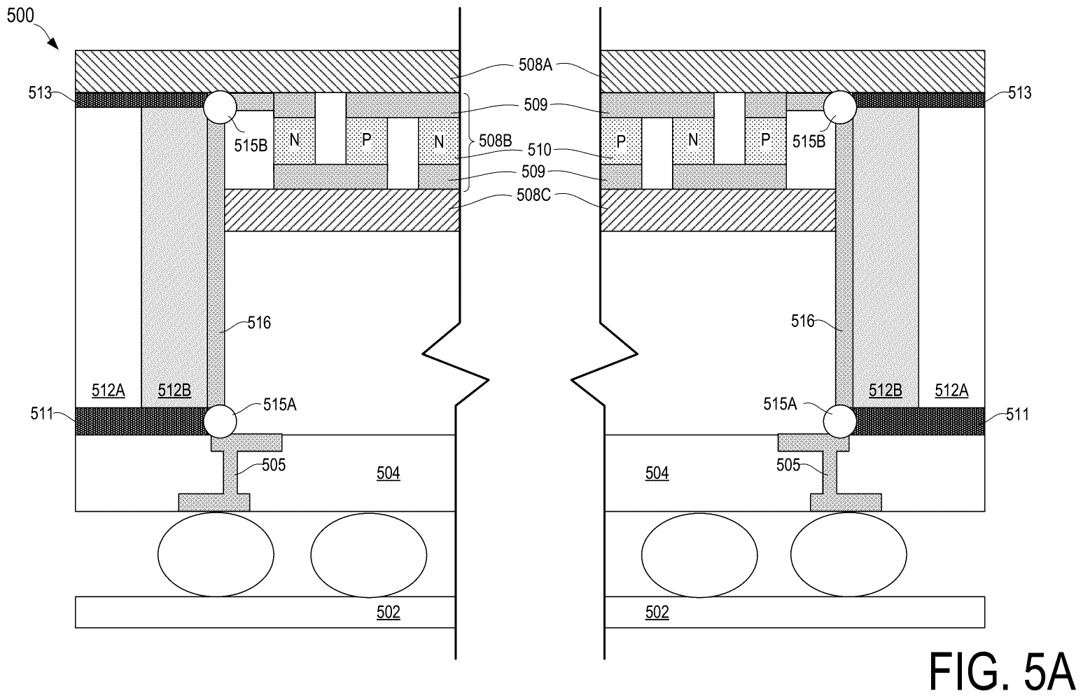

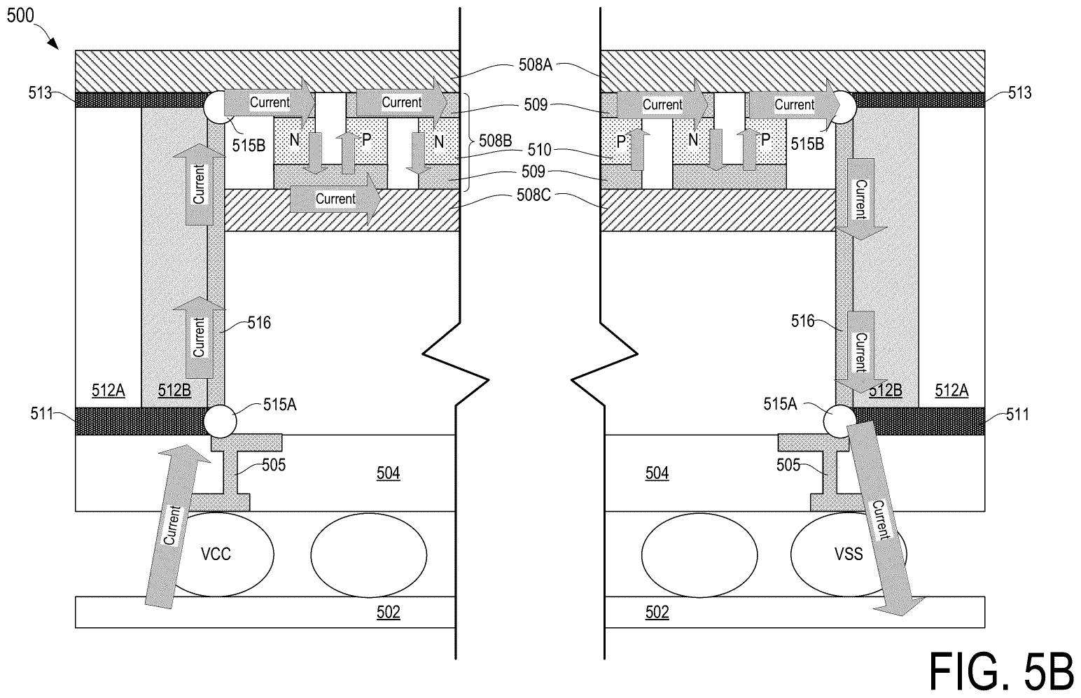

The integrated circuit package 403 also includes a heat spreader to dissipate heat generated by the die 406. The heat spreader encapsulates the die 406 on the package substrate 404 as shown, and is coupled to both the package substrate 404 (via adhesive 411) and to the die 406 (via a thermal interface material (TIM) 407). The heat spreader includes sidewall portions 412 and a Peltier element 408 that is above the die 406. The Peltier element 408 includes a first thermally conductive plate 408A that is positioned on the sidewall portions 412, which may be formed from metal or any other suitable material. The Peltier element 408 also includes a second thermally conductive plate 408C and a layer of p-type and n-type semiconductors 408B between the first and second thermally conductive plates. The p-type and n-type semiconductors 408B may be arranged in any suitable manner to implement a Peltier element, e.g., as shown in FIG. 2 or in FIGS. 5A-5B, which are described further below.

The integrated circuit package 403 further includes an external heatsink or cooling device 414 that is coupled to the top of the heat spreader. The external heatsink/cooling device 414 can be implemented in any suitable manner, e.g., as a passive heatsink, a heatsink with an active fan, a liquid cooling device, or a vapor chamber cooling device. The system 400 also includes a power supply 405 coupled to the circuit board 402, which can provide power to the Peltier element 408 through the circuit board 402 and the package substrate 404.

FIGS. 5A-5B illustrate detailed views of an example heat spreader 500 with an integrated Peltier element in accordance with embodiments herein. In some instances, the example heat spreader 500 may be implemented in the integrated circuit packages 100 of FIG. 1, 300 of FIG. 3, 403 of FIG. 4, or another type of integrated circuit package that includes an integrated heat spreader. In particular, FIG. 5A illustrates a detailed view of an example implementation of a heat spreader with an integrated Peltier element, and FIG. 5B illustrates an example current flow through the heat spreader/Peltier element of FIG. 5A. The examples shown include a circuit board 502 that may be implemented in the same or similar manner as the circuit board 402, and a package substrate 504 that may be implemented in the same or similar manner as the package substrate 404. The heat spreader 500 includes sidewall portions 512A, 512B similar to the sidewall portions 412 of the heat spreader of the integrated circuit package 403. The sidewall portion 512A may be composed of metal or another thermally conductive material, while the sidewall portion 512B may be a dielectric mold material. The sidewall portions 512A, 512B are coupled to the package substrate 504 via adhesive 511.

The heat spreader 500 also includes a Peltier element 508 that is similar to the Peltier element 408 of FIG. 4, and includes a top thermal conductive layer 508A (coupled to the top of the sidewalls 512 by adhesive 513), a bottom thermally conductive layer 508C, and p-type and n-type semiconductor elements 510 in the layer 508B between the thermally conductive layers 508A, 508C. The thermally conductive layers 508A, 508C may be electrically insulating, and may be ceramic in some embodiments. The p-type and n-type semiconductor elements 510 are coupled to the thermally conductive layers 508A, 508C in the layer 508B via an electrically conductive material 509, e.g., metal. The electrically conductive material 509 is arranged to provide a current through the p-type and n-type semiconductor elements 510 as shown in FIG. 5B, i.e., in series through the elements 510 alternating between the p-type and the n-type elements as shown.

To provide the electrical current through the Peltier element 508, the package substrate 504 includes electrically conductive traces 505 (e.g., metal) through its various layers to connect the Peltier element to supply voltages provided by the circuit board 502 through the package substrate 504, e.g., as shown in FIG. 5B. The package also includes electrically conductive traces 516 on the inside of the sidewall portion 512B, which are electrically connected to the traces 505 of the package substrate 504 by electrically connectors 515A and electrically connected to the electrically conductive portion 509 of the Peltier element 508 via electrically connectors 515B. In some embodiments, the electrical connectors 515 may be implemented as Fuzz Buttons®, which can be implemented as a strand of gold-plated beryllium copper wire compressed into a dense, sponge-like cylindrical shape. As shown in FIG. 5B, one side of the Peltier element 508 can be connected to a VCC voltage on one side of the package through these electrical connections, and to a VSS voltage on another side of the package through the electrical connections. The VCC and VSS voltages may be provided, for instance, by a power supply that is coupled to the circuit board 502, e.g., 405 of FIG. 4.

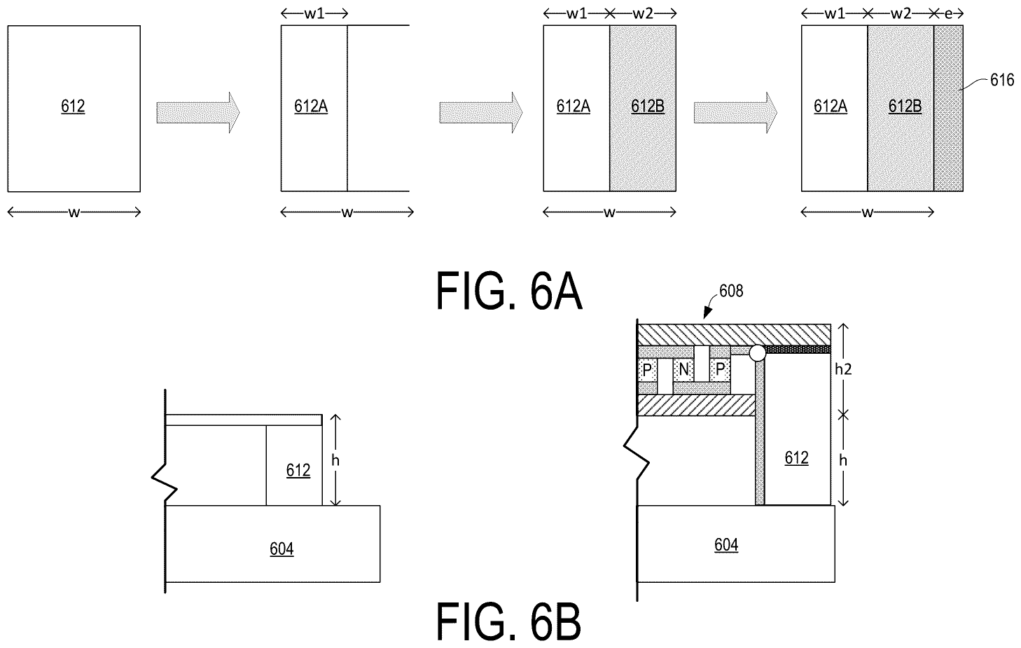

FIGS. 6A-6B illustrate example dimensional changes for embodiments of the present disclosure with respect to current heat spreader solutions. In particular, FIG. 6A illustrates example widths of heat spreader sidewalls and FIG. 6B illustrates example heights of heat spreaders. The left side of FIG. 6A illustrates a sidewall 612 of a typical heat spreader having a thickness of w, which may be on the order of 2-3 mm in certain instances. In embodiments herein, the total wall thickness may remain similar to this thickness w, e.g., approximately 2.5 mm. This can allow for the creation of a cavity within the heat spreader housing (e.g., by CNC manufacturing techniques) in which a mold insert can be placed. That is, the heat spreader sidewalls can be machined to a thickness of w1 (e.g., where w1 is between approximately 1.3-1.7 mm) as shown in the middle images of FIG. 6A, and a dielectric mold insert 612B (e.g., w2 is between 0.8-1.2 mm) can then be placed inside the sidewall. The thickness of the sidewall portion 612A and the mold insert 612B may be approximately the same thickness was a typical heat spreader wall, as shown. Either before or after the mold insert 612B is inserted into the sidewall 612A, the mold insert surface is plated with metal traces 616 (e.g., Cu, Ni, or Au). This may be done using laser direct structuring techniques and can lead to traces with a total thickness as thin as 0.01 mm in certain instances.

Turning to FIG. 6B, the left side illustrates a typical heat spreader with height h above the package substrate 604, with a height of approximately 1.4-1.6 mm (e.g., 1.45 mm). The right side of FIG. 6B illustrates the increased thickness h2 (e.g., 1 mm) that may be seen in the heat spreader due to the incorporation of a Peltier element 608 as shown. This may lead to an overall height of the heat spreader between approximately 2.4-2.6 mm (e.g., 2.45 mm). In some embodiments, the height of the Peltier element may be based on its cooling capacity. For instance, a Peltier element with 30 W of cooling capacity may be approximately 1.6 mm in certain instances.

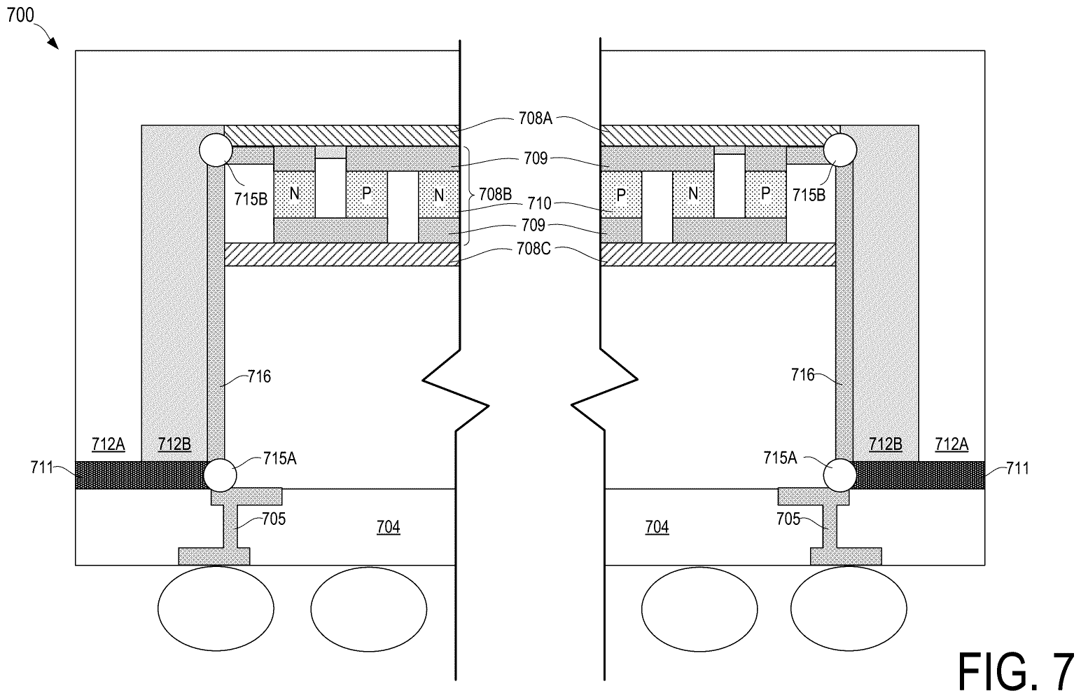

FIG. 7 illustrates detailed views of another example heat spreader 700 with an integrated Peltier element in accordance with embodiments herein. The heat spreader 700 is implemented in a similar manner as the heat spreader 500 of FIGS. 5A-5B, but includes a fully connected outer portion 712A (i.e., a continuous material that encapsulates one or more dies within, and includes both the sidewalls and top portion, to which the Peltier element is coupled for heat transfer) and a dielectric mold 712B inserted within the outer portion 712A. Such an embodiment may be manufactured using aspects described above with respect to FIG. 6A. The Peltier element 708 includes the same set of components as above, but is inserted within the dielectric mold portion 712B rather than making up the entire top portion of the heat spreader. The Peltier element can be placed into position after the mold 712B has been inserted and the traces 716 have been plated and the connectors 715 have been placed. The pre-placed connectors 715 may aid in creating the electrical connections between the traces 716 and the electrically conductive material 709 of the Peltier element 708.

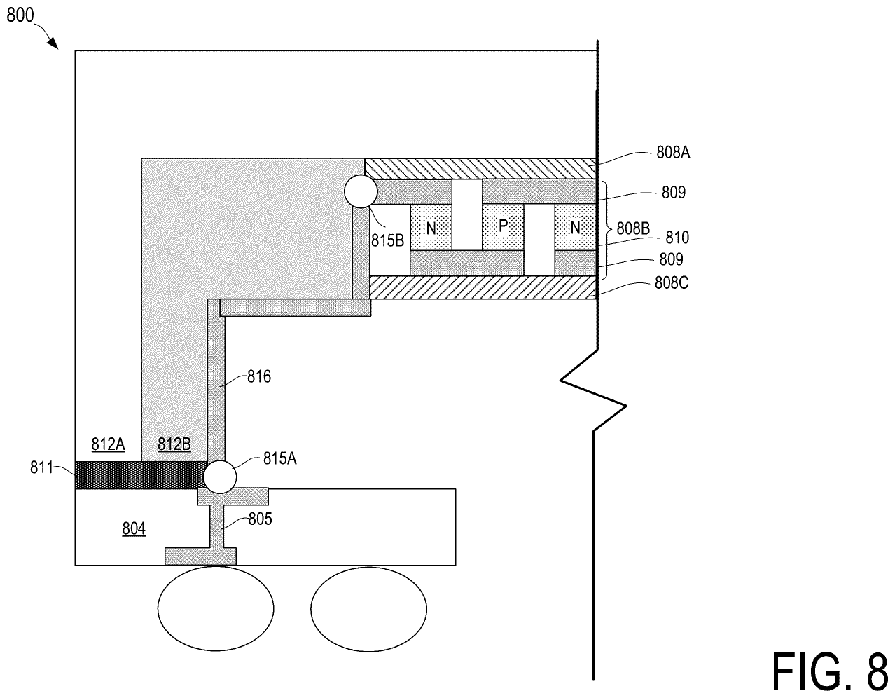

FIG. 8 illustrates detailed views of yet another example heat spreader 800 with an integrated Peltier element in accordance with embodiments herein. In the example shown, the heat spreader 800 is implemented in a similar manner as the heat spreader 700 of FIG. 7, but with the Peltier element 808 embedded further inward with respect to the sidewalls, within a cavity of the dielectric mold portion 812B towards the inside of the top portion of the heat spreader. This way of incorporating a Peltier element may be useful where multiple Peltier elements are included within the heat spreader, e.g., as shown in FIG. 3A. As with the example of FIG. 7, an embodiment such as that shown in FIG. 8 may be manufactured using aspects described above with respect to FIG. 6A. The Peltier element 808 may be inserted within the cavity of the dielectric mold portion 812B after the mold has been inserted within the outer portion 812A and the traces 816 have been plated and the connectors 815 have been placed. The pre-placed connectors 815 may aid in creating the electrical connections between the traces 816 and the electrically conductive material 809 of the Peltier element 808.

In both examples shown in FIGS. 7-8, the Peltier elements 708, 808 are in contact with the thermally conductive outer portions 712A, 812A, respectively, to allow for proper heat transfer from an integrated circuit die or dies coupled to the package substrates 704, 804 and encapsulated within the heat spreaders.

To quantify the improvement in thermal dissipation capability of an integrated circuit package with an embedded Peltier cooler, a simulation was performed based on an Intel® Stratix® 10 FPGA package similar to the one illustrated in FIG. 1, with a primary die power consumption of 100 W and secondary die power consumption of 15 W each, for a total power consumption of 160 W. The simulation was based on a commercially available Peltier element that is 1.6 mm thick with a cooling capacity of 32.4 W, but assuming a 70% efficiency (i.e., 23 W), which may be considered relatively conservative. Table 1 below illustrates these simulation results.

TABLE 1
Simulation results

| | | IHS w/o Peltier | | | | IHS w/Peltier | | | |
|---|---|---|---|---|---|---|---|---|---|
| | | element | | | | element | | | |
| | | Secondary | | Primary | | Secondary | | Primary | |
| | | dies | | Die | | dies | | Die | |
| (A) | Tjmax spec | 100° | C. | 100° | C. | 100° | C. | 100° | C. |
| (B) | Junction Temp, Tj | 98° | C. | 85.8° | C. | 92° | C. | 83.4° | C. |
| | from simulation | | | | | | | | |
| (C) | Design margins | 2° | C. | 14.2° | C. | | | | |
| | from Tjmax spec | | | | | | | | |
| | [(B) − (A)] | | | | | | | | |
| (D) | Tj reduction with | | | | | 6° | C. | 2.4° | C. |
| | embedded Peltier | | | | | | | | |
| | from simulation | | | | | | | | |
| (E) | % Margins Gained | | | | | 300% | | 17% | |
| | with embedded | | | | | | | | |
| | Peltier | | | | | | | | |
| | [(D)/(C)] *100% | | | | | | | | |

It can be seen from the results shown in Table 1 that the secondary die temperatures have been lowered by approximately 6° C. while the primary die temperatures have been lowered by approximately 2.4° C. The margins for thermal design with such an embedded Peltier cooler design have thus greatly increased by 300% for the secondary dies and 17% for the primary die. This demonstrates that Peltier cooling effect can successfully reduce hotspot temperatures created by the secondary dies, which in turn can ease the thermal solution design that is needed to meet temperature requirements of the package.

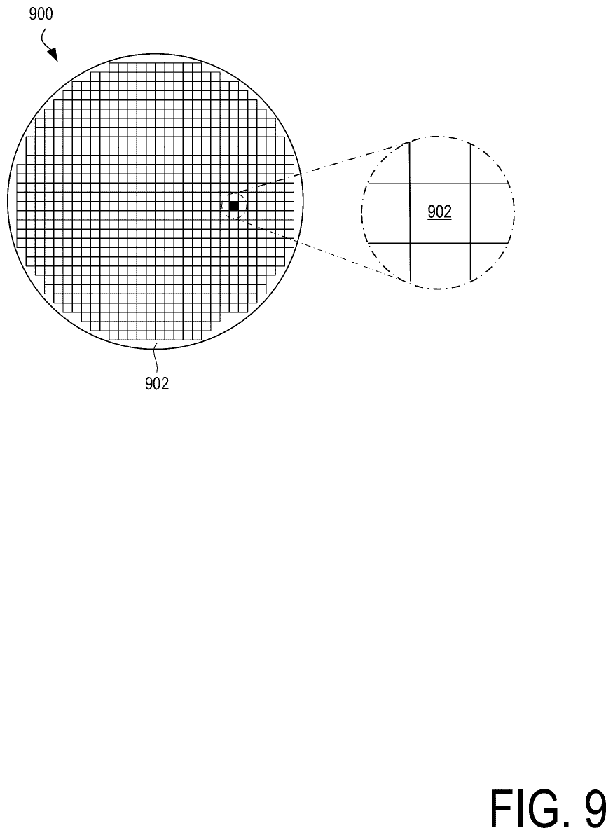

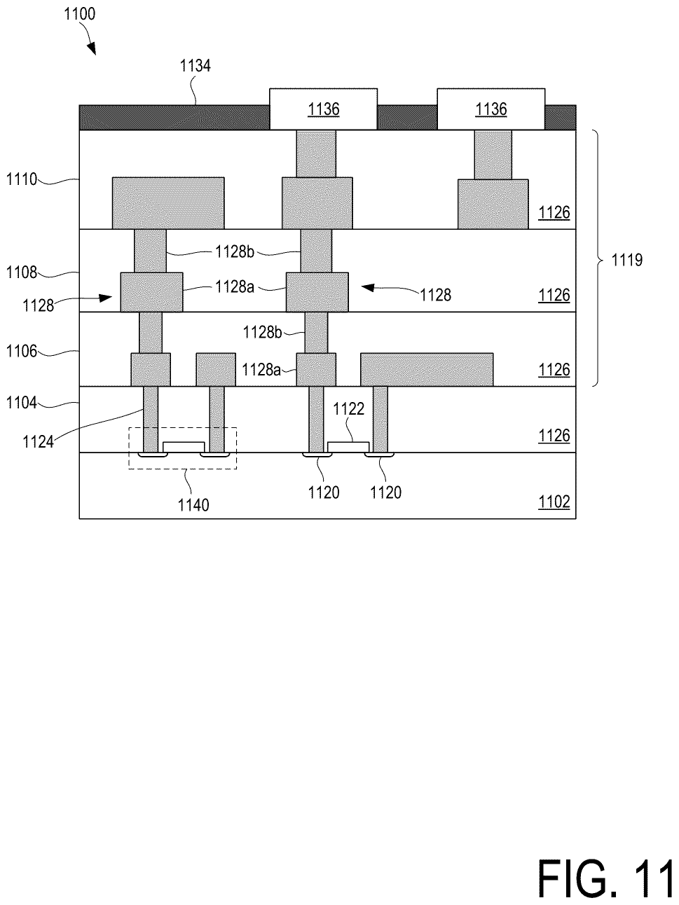

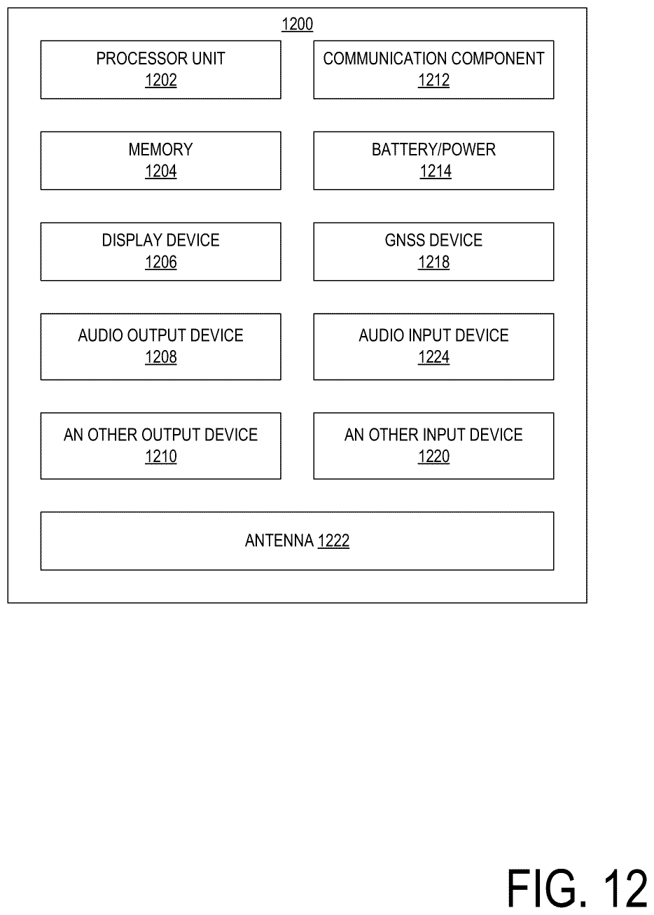

FIG. 9 is a top view of a wafer 900 and dies 902 that may be implemented in or along with any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1140 of FIG. 11, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array.

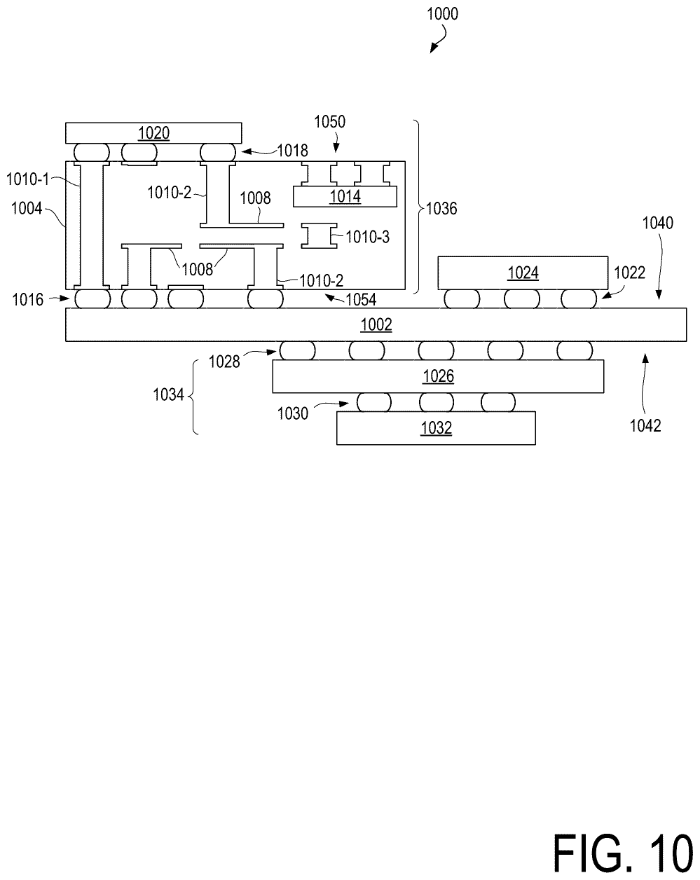

FIG. 10 is a cross-sectional side view of an integrated circuit device assembly 1000 that may include any of the embodiments disclosed herein. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., the die 902 of FIG. 9, the integrated circuit device 1100 of FIG. 11) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a cross-sectional side view of an integrated circuit device 1100 that may be included in any of the embodiments disclosed herein. One or more of the integrated circuit devices 1100 may be included in one or more dies 902 (FIG. 9). The integrated circuit device 1100 may be formed on a die substrate 1102 (e.g., the wafer 900 of FIG. 9) and may be included in a die (e.g., the die 902 of FIG. 9). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 902 of FIG. 9) or a wafer (e.g., the wafer 900 of FIG. 9).

The integrated circuit device 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 11, a transistor 1140 may include a gate 1122 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page and/or in a direction across the page from the perspective of FIG. 11. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the interconnect structures 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (i.e., farther away from the device layer 1104) may be thicker that the interconnect layers that are lower in the metallization stack 1119, with lines 1128a and vias 1128b in the higher interconnect layers being thicker than those in the lower interconnect layers.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board or a package substrate, e.g., 112). The integrated circuit device 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. In some embodiments, TSVs extending through the substrate can be used for routing power and ground signals from conductive contacts on the opposite side of the integrated circuit device 1100 from the conductive contacts 1136 to the transistors 1140 and any other components integrated into the device 1100, and the metallization stack 1119 can be used to route I/O signals from the conductive contacts 1136 to transistors 1140 and any other components integrated into the device 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 12 is a block diagram of an example electrical device 1200 that may include one or more of the embodiments disclosed herein. For example, any suitable ones of the components of the electrical device 1200 may include one or more of assemblies 100, integrated circuit devices 1100, or integrated circuit dies 902 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit package comprising: a package substrate; an integrated circuit die coupled to the package substrate; a heat spreader coupled to the package substrate and the integrated circuit die, the heat spreader comprising a Peltier element above the integrated circuit die.

Example 2 is an integrated circuit package comprising: a package substrate; a plurality of integrated circuit dies coupled to a top side of the package substrate; a heat spreader coupled to the top side of the package substrate and encapsulating the plurality of integrated circuit dies, the heat spreader comprising a Peltier element above at least one of the integrated circuit dies.

Example 3 includes the subject matter of Example 2, wherein the heat spreader comprises a Peltier element above all of the integrated circuit dies.

Example 4 includes the subject matter of Example 2, wherein the heat spreader comprises a Peltier element above a subset of the integrated circuit dies.

Example 5 includes the subject matter of Example 2 or 4, wherein the heat spreader comprises a first Peltier element above a first integrated circuit die and a second Peltier element above a second integrated circuit die.

Example 6 is system comprising: a circuit board; and an integrated circuit package coupled to the circuit board, the integrated circuit package comprising: a package substrate; an integrated circuit die coupled to a top surface the package substrate; a heat spreader coupled to the integrated circuit die and the top surface of the package substrate, the heat spreader comprising a Peltier element above at least one of the integrated circuit dies; and a heatsink coupled to the heat spreader.

Example 7 includes the subject matter of Example 6, further comprising a power source coupled to the circuit board, wherein the Peltier element is coupled to the voltage source through the main board and the package substrate.

Example 8 includes the subject matter of any one of Examples 1-7, wherein the heat spreader comprises a top portion above the integrated circuit die and sidewalls that surround the integrated circuit die, the heat spreader coupled to the package substrate via the sidewalls.

Example 9 includes the subject matter of Example 8, wherein the Peltier element is in the top portion of the heat spreader.

Example 10 includes the subject matter of any one of Examples 8 or 9, further comprising an electrical trace on an inner wall of at least one sidewall, the electrical trace electrically coupling an electrical connector of the package substrate and an electrical connector of the Peltier element.

Example 11 includes the subject matter of any one of Examples 8-10, further comprising: a first electrical connection material coupling the electrical trace and the electrical connector of the package substrate; and a second electrical connection material coupling the electrical trace and the electrical connector of the Peltier element.

Example 12 includes the subject matter of Example 11, wherein the first electrical connection material and the second electrical connection material comprise gold-plated beryllium copper wires.

Example 13 includes the subject matter of any one of Examples 8-12, wherein the sidewalls of the heat spread comprise a metal outer portion and a dielectric portion inside the metal outer portions.

Example 14 includes the subject matter of any preceding Example, wherein the Peltier element comprises p-type and n-type semiconductor elements between a first thermally conductive layer and a second thermally conductive layer.

Example 15 includes the subject matter of any preceding Example, wherein the Peltier element comprises: a first thermally conductive layer; a second thermally conductive layer; p-type semiconductor elements between the first thermally conductive layer and the second thermally conductive layer; n-type semiconductor elements between the first thermally conductive layer and the second thermally conductive layer; and electrically conductive material coupled to the p-type semiconductors and n-type semiconductors and arranged to cause current to flow through the p-type semiconductors and n-type semiconductors in series, alternating between the p-type and the n-type semiconductors.

Example 16 includes the subject matter of any preceding Example, comprising a thermal interface material between the integrated circuit die(s) and the heat spreader.

Example 17 is an integrated circuit package comprising: a package substrate; an integrated circuit die coupled to the package substrate; and a heat spreader coupled to the package substrate and the integrated circuit die, the heat spreader comprising a top portion above the integrated circuit die and sidewalls that surround the integrated circuit die, the top portion comprising: a first thermally conductive layer; a second thermally conductive layer; first semiconductor elements between the first thermally conductive layer and the second thermally conductive layer, the first semiconductor elements comprising silicon and at least one of boron, aluminum, gallium, and germanium; and second semiconductor elements between the first thermally conductive layer and the second thermally conductive layer, the second semiconductor elements comprising silicon and at least one of phosphorous, arsenic, and antimony.

Example 18 includes the subject matter of Example 17, further comprising electrically conductive material coupled to the first semiconductor elements and the second semiconductor elements, and arranged to cause current to flow through the first semiconductor elements and the second semiconductor elements in series, alternating between the first and the second semiconductor elements.

Example 18 includes the subject matter of Example 17 or 18, further comprising an electrical trace on an inner wall of at least one sidewall, the electrical trace electrically coupling an electrical connector of the package substrate and an electrical connector of the top portion connected to the first and second semiconductor elements.

Example 19 includes the subject matter of Example 18, further comprising: a first electrical connection material coupling the electrical trace and the electrical connector of the package substrate; and a second electrical connection material coupling the electrical trace and the electrical connector of the top portion connected to the first and second semiconductor elements.

Example 20 includes the subject matter of Example 19, wherein the first electrical connection material and the second electrical connection material comprise gold-plated beryllium copper wires.

Example 21 includes the subject matter of any one of Examples 17-20, wherein the first thermally conductive layer comprises a ceramic and the second thermally conductive layer comprises a ceramic.

Example 22 includes the subject matter of any one of Examples 17-21, wherein the sidewalls of the heat spreader comprise a metal outer portion and a dielectric portion inside the metal outer portions.

Example 23 includes the subject matter of any one of Examples 17-22, wherein at least a portion of a top surface of the heat spreader comprises the first thermally conductive layer and the second thermally conductive layer is coupled to the integrated circuit die via a thermal interface material.

Example 24 includes the subject matter of any one of Examples 17-22, wherein a top surface of the heat spreader is in contact with the first thermally conductive layer and the second thermally conductive layer is coupled to the integrated circuit die via a thermal interface material.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). Additionally, it should be appreciated that items included in a list in the form of “at least one of A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact. Further, “adjacent” may refer to layers or components that are in physical contact with each other. That is, there is no layer or component between the stated adjacent layers or components. For example, a layer X that is adjacent to a layer Y refers to a layer that is in physical contact with layer Y.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, “located on” in the context of a first layer or component located on a second layer or component may refer to the first layer or component being directly physically attached to the second part or component (no layers or components between the first and second layers or components) or physically attached to the second layer or component with one or more intervening layers or components.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit package comprising:
a package substrate;
an integrated circuit die coupled to the package substrate; and
a heat spreader coupled to the package substrate and the integrated circuit die, the heat spreader comprising a top portion above the integrated circuit die and sidewalls that surround the integrated circuit die, the top portion comprising:
a first thermally conductive layer;
a second thermally conductive layer;
first semiconductor elements between the first thermally conductive layer and the second thermally conductive layer, the first semiconductor elements comprising silicon and at least one of boron, aluminum, gallium, and germanium; and
second semiconductor elements between the first thermally conductive layer and the second thermally conductive layer, the second semiconductor elements comprising silicon and at least one of phosphorous, arsenic, and antimony.

2. The integrated circuit package of claim 1, further comprising electrically conductive material coupled to the first semiconductor elements and the second semiconductor elements, and arranged to cause current to flow through the first semiconductor elements and the second semiconductor elements in series, alternating between the first and the second semiconductor elements.

3. The integrated circuit package of claim 1, further comprising an electrical trace on an inner wall of at least one sidewall, the electrical trace electrically coupling an electrical connector of the package substrate and an electrical connector of the top portion connected to the first and second semiconductor elements.

4. The integrated circuit package of claim 3, further comprising:
a first electrical connection material coupling the electrical trace and the electrical connector of the package substrate; and
a second electrical connection material coupling the electrical trace and the electrical connector of the top portion connected to the first and second semiconductor elements.

5. The integrated circuit package of claim 4, wherein the first electrical connection material and the second electrical connection material comprise gold-plated beryllium copper wires.

6. The integrated circuit package of claim 1, wherein the first thermally conductive layer comprises a ceramic and the second thermally conductive layer comprises a ceramic.

7. The integrated circuit package of claim 1, wherein the sidewalls of the heat spreader comprise a metal outer portion and a dielectric portion inside the metal outer portions.

8. The integrated circuit package of claim 1, wherein at least a portion of a top surface of the heat spreader comprises the first thermally conductive layer and the second thermally conductive layer is coupled to the integrated circuit die via a thermal interface material.

9. The integrated circuit package of claim 1, wherein a top surface of the heat spreader is in contact with the first thermally conductive layer and the second thermally conductive layer is coupled to the integrated circuit die via a thermal interface material.

10. An integrated circuit package comprising:
a package substrate;
a plurality of integrated circuit dies coupled to a top side of the package substrate; and
a heat spreader coupled to the top side of the package substrate and encapsulating the plurality of integrated circuit dies, the heat spreader comprising a Peltier element above at least one of the integrated circuit dies.

11. The integrated circuit package of claim 10, wherein the heat spreader comprises a Peltier element above all of the integrated circuit dies.

12. The integrated circuit package of claim 10, wherein the heat spreader comprises a Peltier element above a subset of the integrated circuit dies.

13. The integrated circuit package of claim 10, wherein the heat spreader comprises a first Peltier element above a first integrated circuit die and a second Peltier element above a second integrated circuit die.

14. The integrated circuit package of claim 10, wherein the Peltier element comprises p-type and n-type semiconductor elements between a first thermally conductive layer and a second thermally conductive layer.

15. The integrated circuit package of claim 10, wherein the heat spreader comprises a top portion above the integrated circuit dies and sidewalls that surround the integrated circuit dies, the heat spreader coupled to the package substrate via the sidewalls, the Peltier element in the top portion of the heat spreader.

16. The integrated circuit package of claim 10, comprising an electrical trace on an inner wall of the heat spreader, the electrical trace electrically coupling an electrical connector of the package substrate and an electrical connector of the Peltier element.

17. A system comprising:
a circuit board; and
an integrated circuit package coupled to the circuit board, the integrated circuit package comprising:
a package substrate;
an integrated circuit die coupled to a top surface the package substrate;
a heat spreader coupled to the integrated circuit die and the top surface of the package substrate, the heat spreader comprising a Peltier element above at least one of the integrated circuit dies; and
a heatsink coupled to the heat spreader.

18. The system of claim 17, wherein the Peltier element comprises p-type and n-type semiconductor elements between a first thermally conductive layer and a second thermally conductive layer.

19. The system of claim 17, wherein the heat spreader comprises a top portion above the integrated circuit die and sidewalls that surround the integrated circuit die, the heat spreader coupled to the package substrate via the sidewalls, the Peltier element in the top portion of the heat spreader, and the integrated circuit package further comprises an electrical trace on an inner wall of at least one sidewall of the heat spreader, the electrical trace electrically coupling an electrical connector of the package substrate and an electrical connector of the Peltier element.

20. The system of claim 17, further comprising a power source coupled to the circuit board, wherein the Peltier element is coupled to the voltage source through the main board and the package substrate.
